(19) United States
(12) Patent Application Publication
(10) Pub. No.: US 2008/0213418 A1
(43) Pub. Date: Sep. 4, 2008

(54) ALIGN-TRANSFER-IMPRINT SYSTEM FOR IMPRINT LITHOGRPHY

(76) Inventors: Hua Tan, Princeton Junction, NJ (US); Wei Zhang, Plainsboro, NJ (US); He Gao, Plainsboro, NJ (US); Linshu Kong, Plainsboro, NJ (US); Lin Hu, Livingston, NJ (US); Colby Steere, Parsippany, NJ (US); Stephen Y. Chou, Princeton, NJ (US)

Correspondence Address: POLSTER, LIEDER, WOODRUFF & LUCCHESI, 12412 POWERSCOURT DRIVE SUITE 200, ST. LOUIS, MO, 63131-3615, US

(21) Appl. No.: 11/931,280

(22) Filed: Oct. 31, 2007

Related U.S. Application Data
(63) Continuation-in-part of application No. 10/926,376, filed on Aug. 25, 2004, now Pat. No. 7,322,287.
Application No. 10/926,376 is a continuation-in-part of application No. 10/140,140, filed on May 7, 2002, now Pat. No. 7,137,803.
Application No. 10/140,140 is a division of application No. 09/618,174, filed on Jul. 18, 2000, now Pat. No. 6,482,742.
(60) Provisional application No. 60/916,080, filed on May 4, 2007.

(51) Int. Cl. H01L 21/304

(52) U.S. Cl. 425/112

(57) ABSTRACT

An imprint system for imprint lithography comprises an alignment subsystem and an imprint subsystem. The mask (mold) and the wafer for imprinting (substrate) are align on the alignment subsystem and contacted to each other to form a mask/wafer set. The mask/wafer set is then transferred onto the imprint subsystem while alignment is maintained. The mask/wafer set is then imprinted on the imprint subsystem. During transfer, the mask/wafer set can be held in alignment by surface. The surface adhesion can be enhanced by local pressing, local heating, or both. Alternatively, the mask/wafer set can be held in alignment by clamping. Advantageously, the imprinting is effected by fluid pressure imprinting.

### CROSS-REFERENCE TO RELATED APPLICATIONS

This application claims the benefit of U.S. Provisional Application Ser. No. 60/916,980 filed by Hua Tan, et al. on May 4, 2007 and which is incorporated herein by reference.

This application is a continuation-in-part of U.S. patent application Ser. No. 10/926,376 filed by Hua Tan, Linshu Kong, Mingtao Li, Stephen Y. Chou, on Aug. 25, 2004 and entitled “Apparatus For Fluid Pressure Imprint Lithography” which, in turn, is a continuation-in-part of U.S. patent application Ser. No. 10/140,140 filed by Stephen Y. Chou on May 7, 2002, which, in turn, is a divisional of U.S. patent application Ser. No. 09/618,174 filed by Stephen Y. Chou on Jul. 18, 2000 (now U.S. Pat. No. 6,482,742 issued on Nov. 19, 2002). The foregoing '376 application, the '140 application, and the '174 applications are each incorporated herein by reference.

### FIELD OF INVENTION

This invention generally relates to a system for imprint lithography such as microscale and nanoscale imprint lithography. It is particularly useful for imprint lithography involving multiple aligned layers.

### BACKGROUND OF THE INVENTION

Lithography is a key process in the fabrication of semiconductor devices such as integrated circuits and many optical, magnetic, biological and micromechanical devices. Lithography creates a pattern on a substrate-supported layer so that in subsequent process steps, the pattern can be replicated in the substrate or in a surface that is added onto the substrate.

Conventional lithography, referred to as optical lithography, involves applying a thin film of photosensitive resist onto a substrate, exposing the resist to a desired pattern of radiation and developing the exposed resist to produce a physical pattern overlying the substrate. A typical application is step-and-repeat optical lithography wherein a patterned area much smaller than the substrate is replicated many times on the substrate. Step-and-repeat optical lithography exposes a first pattern on the substrate, moves the substrate to a new position for a new exposure and repeats the process many times to substantially cover the substrate. This approach has been the mainstream method of patterning semiconductor substrates in integrated circuit manufacture.

Unfortunately, step-and-repeat optical lithography is limited in attainable resolution and requires increasingly expensive equipment as these limits are approached. As the critical dimensions of devices shrink smaller than the wavelength of exposure light, the cost of equipping and operating optical stepper technology increases beyond the affordability of small businesses. Moreover, optical lithography becomes too expensive for many potential device applications other than integrated circuits. For example, a state-of-the-art optical stepper costs about $25 million per tool and requires a team of about 10 technicians working day and night to keep it running properly. Moreover, optical lithography has smallest achievable features that are too large for many potential new devices desired for nanotechnology.

Imprint lithography, based on a fundamentally different principle, is a promising technology for replacing optical lithography in many applications. In imprint lithography, a mold with a pattern of projecting and recessed features is pressed into a moldable surface on a substrate (typically a thin polymer film), and imprints into the film the features of the mold. After the mold is removed, the thin film can be further processed, as by removing the residual reduced thickness portions of the film, to expose the underlying substrate.

As compared to optical lithography, imprint lithography offers substantial advantages of high resolution, low cost and large area coverage. While optical lithography is fundamentally limited by the wavelength of the exposure light, imprint lithography provides very high nanoscale resolution smaller than attained by visible or even ultraviolet optical lithography. Moreover, imprint lithography can be practiced by relatively inexpensive molding equipment. Thus, imprint lithography has promise not only for the fabrication of integrated circuits but also for smaller scale production of desired biological, optical and nanoscale devices.

To have a workable device, multiple layers of patterns of different materials are laid down one on top of another with high overlay accuracy. Higher performance may need higher overlay accuracy. To fabricate such devices, it normally requires lithography capable of making a layer of pattern on top of another layer of pattern with precise alignment between the two layers. To use imprint lithography to produce nanoscale devices, imprint lithography must be capable of aligning the mold and the coated substrate and maintaining the alignment until the mold is imprinted into the coated substrate. Optical lithography needs only to align the mask and the wafer, then, light exposure is performed without any moving of the aligned mask and wafer. In imprint lithography, however, the mold and substrate must be aligned, and imprinted without relative lateral shift.

The usual approach is to first align mask and wafer on align stages and then to apply pressing force on the stages to imprint. However, to integrate stages and imprint apparatus together for high performance is too complex and difficult. Furthermore, applying pressing force for imprint on align stages will severely degrade performance and reliability of the align stages. Thus, it is very hard using the conventional approach to achieve high performance imprint together with precise alignment.

### SUMMARY OF THE INVENTION

An imprint system for imprint lithography comprises an alignment subsystem and an imprint subsystem. The mask (mold) and the wafer for imprinting (substrate) are aligned on the alignment subsystem and contacted to each other to form a mask/wafer set. The mask/wafer set is then transferred onto the imprint subsystem while alignment is maintained. The mask/wafer set is then imprinted on the imprint subsystem. During transfer, the mask/wafer set can be held in alignment by surface adhesion. The surface adhesion can be enhanced by local pressing, local heating, or both. Alternatively, the mask/wafer set can be held in alignment by clamping. Advantageously, the imprinting is effected by fluid pressure imprinting.

### BRIEF DESCRIPTION OF THE SEVERAL VIEWS OF THE DRAWINGS

The advantages, nature and various additional features of the invention will appear more fully upon consideration of the illustrative embodiments described in connection with the accompanying drawings. In the drawings:

FIG. 1 is a flow chart to show a typical process of imprint lithography.

FIG. 2 illustrates an align-transfer-imprint method.

FIG. 3 shows use of mechanical clamps to hold a mold and substrate for transfer.

FIG. 4 illustrates another scheme of using mechanical clamps to hold a mold and a substrate for transfer.

FIG. 5 shows use of surface adhesion to hold a mold and substrate for transfer.

FIG. 6 illustrates the use of local pressing to enhance surface adhesion between a mold and substrate.

FIG. 7 illustrates the use of local heating to enhance surface adhesion between a mold and substrate.

FIG. 8 shows the use of an adhesive layer to hold mold and substrate for transfer.

FIG. 9 illustrates the use of direct fluid pressure imprinting to achieve good overlay accuracy.

FIG. 10 is a schematic overview of an align-transfer-imprint system.

FIG. 11 shows the alignment subsystem of the align-transfer-imprint system.

FIG. 12 shows the alignment prepress stage of the alignment subsystem.

FIG. 13 illustrates a leveling scheme to level the wafer with the mask on the alignment prepress stage.

FIG. 14 shows a prepress wafer chuck for the alignment prepress stage.

FIG. 15 shows the imprint-subsystem of the align-transfer-imprint system.

FIG. 16 illustrates a transfer clamp fixture of the align-transfer-imprint system.

FIGS. 17 and 18 illustrate a sealing arrangement of the imprint subsystem of the align-transfer-imprint system.

FIG. 19 shows further details of the sealing arrangement of FIGS. 17 and 18.

FIG. 20 illustrates an alternative sealing arrangement to that of FIGS. 17 and 18.

FIG. 21 shows a substrate holder for the imprint subsystem.

FIGS. 22A and 22B illustrate mechanisms of the imprint subsystem to hold flexible sealing membrane onto their support structures.

FIG. 23 shows an actuator assembly of the imprint subsystem to seal and open sealing membranes.

FIGS. 24 and 25 illustrate a separator of the imprint subsystem for mask/wafer separation; and

FIG. 26 illustrates a chuck of the separator.

### DETAILED DESCRIPTION OF THE INVENTION

Imprint lithography is particularly useful in the replication of patterns having microscale and nanoscale features. Imprint lithography can be divided into thermal imprint lithography and UV (ultraviolet light) imprint lithography. Thermal imprint lithography uses a thermal plastic polymer or a thermal curable polymer as a resist. UV imprint lithography uses a UV curable polymer as resist. In thermal imprint lithography, the polymer is heated to a flowing condition before or during imprinting and permitted to cool to retain the imprint. In UV imprint lithography, the polymer is applied as a liquid, imprinted and then cured by UV exposure to retain the imprint.

Generally, the substrate and the mold are prepared prior to imprinting. A moldable polymer layer is applied on the substrate as by spinning, dropping or deposition. The mold is provided with a topological surface variation (projecting and recessed features) that are to be imprinted into the moldable polymer. A thin anti-sticking layer is generally coated on the mold surface to facilitate complete surface release from the polymer after imprinting.

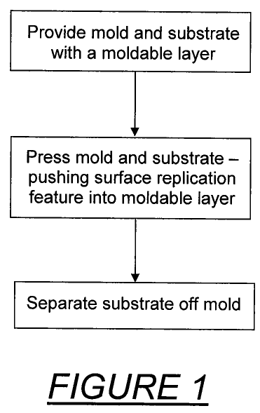

As schematically illustrated in FIG. 1, the process of imprinting can be considered as three steps: 1) providing a mold for replicating the desired pattern and a substrate having a moldable layer ready for imprinting; 2) pressing the mold and the substrate together; and 3) separating the mold from the substrate. At the pressing step, the surface replication features on the mold are pushed into the moldable polymer on the substrate. For a thermal plastic polymer, it is required to heat the polymer above its plastic transition temperature so that it will flow. Thermal curable polymers and UV curable polymers are typically liquid before they are set or cured. They can be deformed without special treatment. When the surface replication features are completely pushed into moldable polymer layer, the polymer is hardened to become non-deformable for expected operating pressures and temperatures of the product. Thermal plastic polymer is hardened by cooling polymer below its plastic transition temperature. Thermal curable polymer is hardened by heating the polymer to its setting temperature. UV curable polymer is hardened by UV radiation with sufficient exposure dose to initiate molecular crosslinking.

The next step in imprinting is to separate the substrate from the mold. A surface anti-sticking coating is generally applied on the mold surface to promote a clean and complete separation of the moldable layer from the mold surface. An adhesion promotion layer may be applied to the substrate surface underneath the moldable layer to hold the moldable layer to the underlying substrate material. After separation, the surface replication features of the mold are imprinted in the moldable layer. Additional processing may be needed to remove any residual layer of polymer in reduced thickness regions imprinted by projecting mold features. In important applications, the substrate may include a previously made pattern, and in such applications, the imprinting typically must be made in precise alignment with the pre-made pattern.

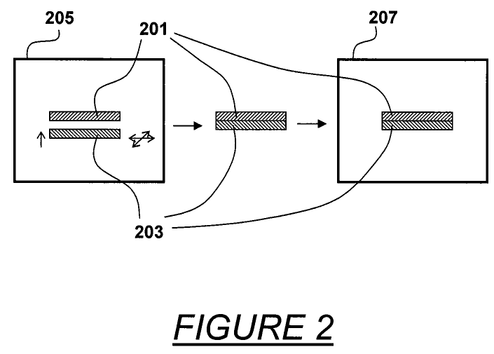

FIG. 2 illustrates an align-transfer-imprint system to imprint a patterned layer that overlies a pre-made pattern on a substrate with high overlay accuracy between the two patterns. A mold 201 and a substrate 203 are aligned to each other on an alignment module or subsystem 205. Once mold 201 and substrate 203 are in contact, the mold is secured to the substrate. The alignment at subsystem 205 comprises leveling the mold and the substrate, relatively moving them into lateral alignment, and adhering the mold and substrate into a mold/substrate assembly, as by pressing them in contact with a pressure that is typically less than required for the desired imprinting (sub-imprint pressing). The resulting mold/substrate assembly is then transferred from the alignment subsystem 205 to an imprint module or subsystem 207 without changing the relative position between the mold and the substrate. The mold 201 is then imprinted into the substrate 203. The term “substrate” as used herein can include a single material body or a multilayer body. The substrate typically includes a solid body such as a silicon wafer and a moldable coating, such as a polymer layer, to be imprinted.

Aligning the mold and the substrate on subsystem 205 can use various alignment techniques. A common align technique is to align the marks on the mold directly to the marks on the substrate. In such case, either one of the mold and the substrate should have visible alignment marks. An alternative alignment technique is that the marks on the mold are aligned to a third set of marks, which have a known position relation to the marks on the substrate, so that a precision moving system can move the mold to the desired location on the substrate. Alternatively, the marks on the substrate are aligned to a third set of marks, which have a known position relation to the marks on the mold, so that a precision moving system can move the substrate to the desired location on the mold. A third alternative is that the mold and the substrate are aligned respectively to two separate intermediate alignment marks and there is a fix position relation between the two intermediate alignment marks. A mechanical system brings the mold and the substrate into a aligned position. The alignment marks can be optical (crosses, interferences, Moiré patters) or electrical (capacitive or conductive, or inductive). The optical illumination of the marks have a wavelength from 10 nm to 10 um. State-of-art imaging processing technique also permits aligning the marks on the mold or the substrate to pre-captured and stored images of the marks on the substrate or the mold.

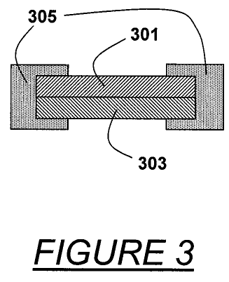

FIGS. 3 through 9 illustrate a variety of retaining mechanisms for maintaining the mold and substrate in alignment prior to imprinting. Mold and substrate alignment can be maintained by one or more of mechanical clamping, surface adhesion between the mold and the coated substrate, and adhesive bonding.

FIG. 3 shows use of mechanical clamping to hold the mold and the substrate in alignment. Mechanical clamps 305 press mold 301 and substrate 303 at their edges. Advantageously, the clamps do not contact the center regions of the mold or substrate.

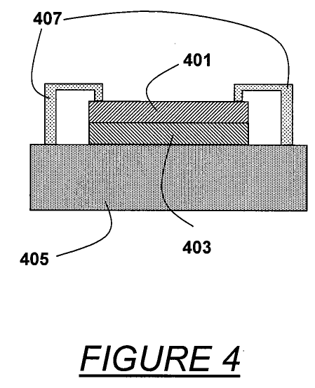

FIG. 4 shows another scheme of using mechanical clamps 407 to hold the mold 401 and the substrate 403 aligned. Mold 401 and substrate 403 sit on a solid surface body 405. Mechanical clamps 407 mounted on body 405 press the mold and the substrate from the top against the solid surface of the underlying body 405. The mechanical clamping force prevents the aligned mold/substrate set from relative shift during transfer.

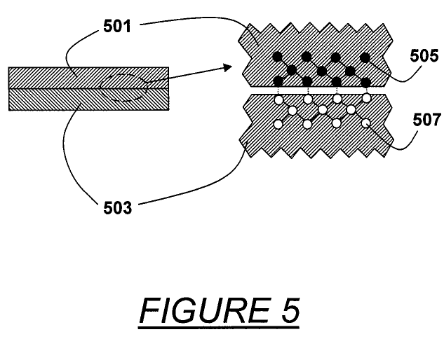

FIG. 5 shows the use of surface attraction (also called “surface adhesion”) to hold the mold and the substrate in alignment. With appropriate materials, when the surface of mold 501 contacts the surface of substrate 503, the surfaces attract one another. The surface attraction force can be generated by molecular interaction of mold surface molecules 505 and substrate surface molecules 507. The surface attraction effects surface adhesion to hold relative positioning of mold 501 and substrate 503. The mold/substrate set is advantageously handled gently during transfer.

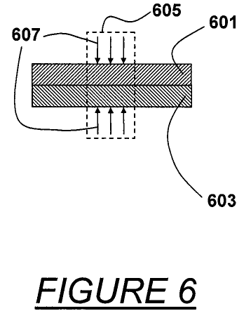

As illustrated in FIG. 6, the surface adhesion may be enhanced by pre-imprint pressing force in order to intentionally control locations of adhesion. For example, surface adhesion may be locally enhanced by applying local pressing force represented by arrows 607 on both mold 601 and substrate 603 across a local area 605.

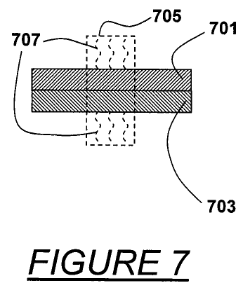

Referring to FIG. 7, surface adhesion may be also enhanced by heating one or more local areas. Local heating (e.g. heat radiation 707) is applied on both mold 701 and substrate 703 across local area 705. Both local pressing and local heating may be used together to enhance surface adhesion. The area where surface adhesion is enhanced may be a single point, multiple points, a single strip or multiple strips.

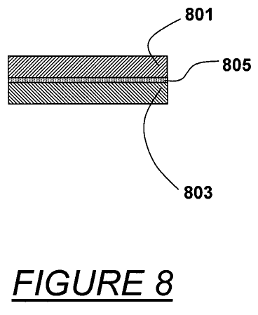

FIG. 8 shows use of an adhesive layer 805 to bond the mold and substrate in alignment. Adhesive layer 805 is sandwiched between mold 801 and substrate 803. The adhesive forms a strong bond to prevent any relative shift. Prior to alignment, the adhesive layer may be applied on mold 801, on the substrate 803 or on both by using spinning, dropping or vapor deposition. Advantageously, the adhesive is one that consolidates into the polymer layer on the substrate after imprinting. The adhesive should be one that does not deteriorate imprinting.

The aligned mold/substrate set is then transferred to the imprint subsystem. Preferably the imprint subsystem is connected to the alignment subsystem in close adjacency. The transfer can be manual or automatic, as by a moveable chuck or a moving conveyor belt.

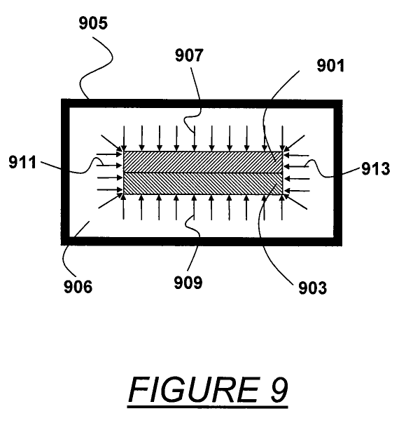

The imprint station can use direct fluid pressure or high precision mechanical pressing for imprinting. Direct fluid pressure is preferred since it minimizes relative shift of mold and substrate during imprinting. In direct fluid pressing, the interface between the mold and the substrate is sealed, and the thus-sealed assembly is subjected to pressurized fluid. FIG. 9 illustrates an advantageous fluid pressure station wherein pressurized gas 906 is filled into chamber 905 to press mold 901 against substrate 903 by gas pressure. Because gas pressure is uniform everywhere inside chamber 905, the pressure force 907 is exactly equal to the bottom pressure 909 everywhere across the area of the mold and substrate. The left side pressure 911 is exactly equal to the right side pressure 913. The symmetry of pressure prevents possible relative shift during imprinting. Therefore, good alignment accuracy can be achieved. Further details concerning direct fluid pressure imprint are set forth in U.S. Pat. No. 6,482,742 issued to Stephen Chou which is incorporated herein by reference.

FIGS. 10 to 16 illustrate an exemplary align-transfer-imprint system in accordance with the invention. The system includes an imprint subsystem 1003, and an alignment subsystem 1001. The subsystems are advantageously firmly attached together in close adjacency on a stable platform to facilitate operation and transfer. In such way, transferring and tool operation have less vibration and handling procedure in order to minimize possibility of causing relative shift of aligned mask/wafer set. Furthermore, building on same strong frame make precision automation easier. The mold and the wafer are aligned on alignment subsystem 1001. The mold/wafer set is transferred into imprint subsystem 1003 through a loading/unloading door 1005. The mold/wafer set is kept aligned during transfer and is imprinted in subsystem 1003.

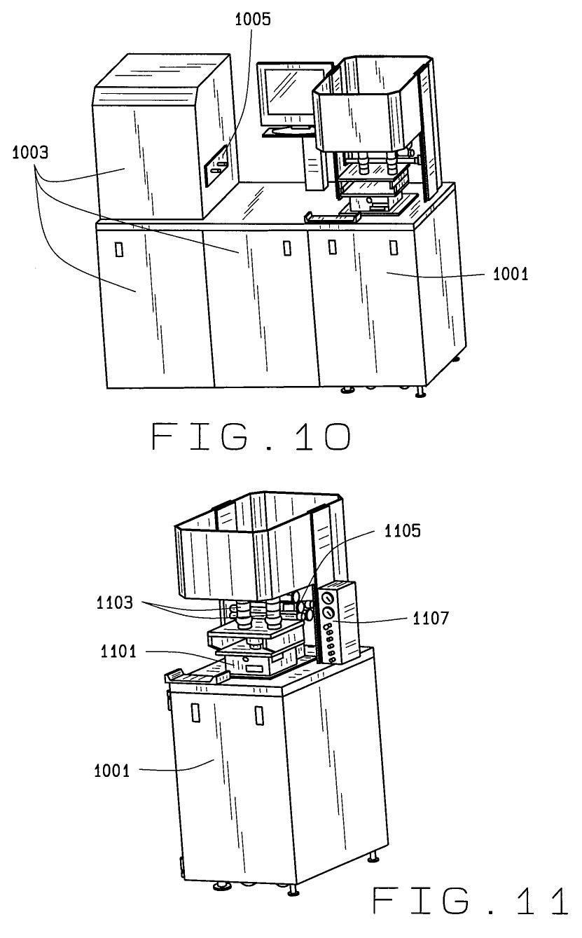

FIG. 11 schematically shows a typical alignment subsystem 1001. The alignment subsystem comprises alignment stages 1101, microscopes 1103, microscope station 1105, and a pneumatic control 1107. The microscopes are typically mounted above the alignment stage. The microscopes are typically moveable horizontally in the lateral X and Y directions and vertically in the Z direction. The pneumatic control can be used to control vacuum and pressurized gas lines of the subsystem.

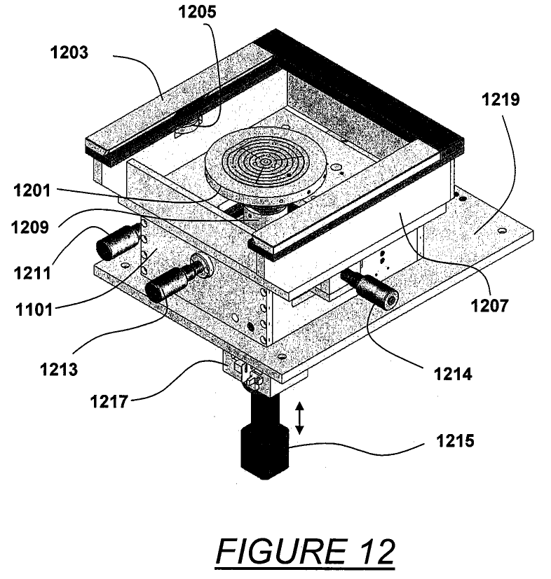

FIG. 12 shows an exemplary alignment stage 1101. A first linear motion stage 1214 is mounted adjacent a second linear motion stage 1213. Linear motion stage 1213 can be firmly attached to a base plate 1219. The traveling directions of the first and second linear motion stages can be perpendicular to each other to provide horizontal movements in the X and Y directions. The two lineal motion stages can have overlapping central open areas. Through the open areas, a frame 1217 can be attached on top of linear motion stage 1214. The frame and all attached parts can move together with the X, Y linear motion stages.

A linear motorized actuator 1215 can be attached to bottom of the frame 1217. Above the actuator, a precision linear bearing (not shown) can be attached by its housing to the frame, and its moving rod can sit on the top end of the actuator. The actuator can push the moving rod up and down precisely. The actuator may include a positioning encode to indicate the vertical position of the moving rod. A rotation arm (not shown) can be laterally attached to the moving rod. The arm can be connected to an adjusting micrometer 1211. The micrometer adjustment pushes the arm and causes the moving rod rotating in X-Y plane. An adapter 1209 is attached to top end of the moving rod. A wafer chuck 1201 is located on top of the adapter. The wafer chuck is able to tilt at small angle on top of the adapter. A housing 1207 is installed to enclose these parts and support a mask chuck frame 1203. In operation, a mask chuck can slide into frame 1203 and lock firmly to the frame by a locking cylinder 1205.

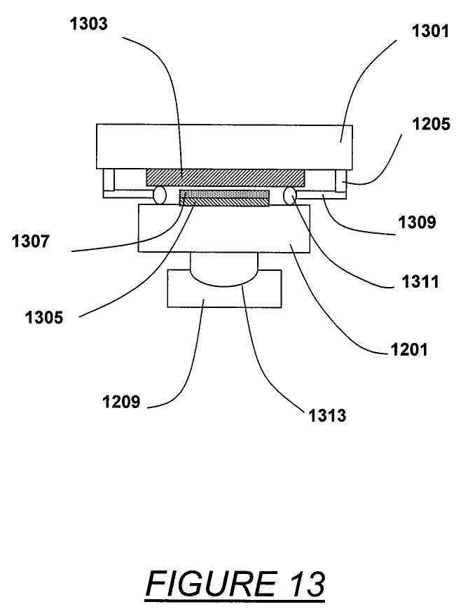

FIG. 13 shows exemplary apparatus to level the wafer surface to the mask surface. Mask 1303 is held against wafer chuck 1301 by vacuum. Wafer is held on wafer chuck 1201. Wafer chuck 1201 is connected to adapter 1209 through a curved contact surface 1313. The contact surface is very smooth in order to allow the wafer chuck to tilt freely over a small surface angle. Vacuum can be applied to the contact surface to lock the wafer chuck against the adapter. During leveling, equal size precision balls 1311 (here three balls) are inserted between the wafer chuck surface and the mask chuck surface. Each precision ball is attached to a movable arm 1309. When the wafer chuck is pushed against the mask chuck through the balls, the wafer chuck tilts freely to orient its surface parallel to the mask chuck surface. After the leveling is complete, vacuum can be applied to contact surface 1313 to lock the wafer chuck. The vacuum can be maintained until desired process is finished. After locking, the wafer chuck can be lowered to permit retraction of the precision balls outside the perimeter of the wafer chuck surface. After the leveling, the wafer surface is level (parallel) with the mask surface.

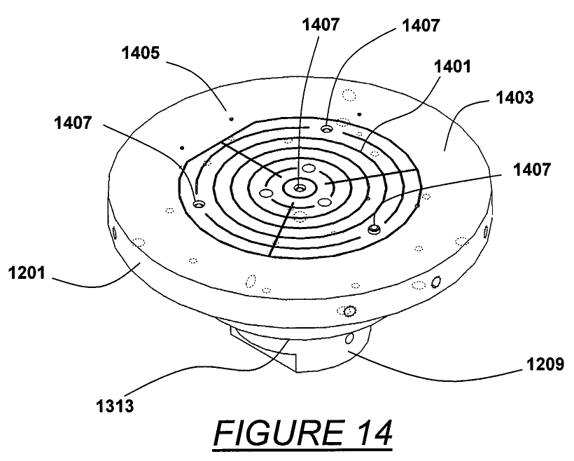

Referring to FIG. 14, wafer chuck 1201 is attached to adapter 1209 through curved contact surface 1313. The wafer chuck has a very flat surface 1403. Pushing pins 1407 can be embedded into the surface. One pin 1407 can be located at the center, and three pins can be distributed evenly along the perimeter of a circle centered about the center of the chuck. The diameter of the circle should be smaller than the wafer. The gap between the circle and the wafer is preferably in a range of 1 mm to 50 mm, depending on wafer size. The pushing pins have ball shaped or flat ends of preferably soft material. The ends are normally retracted below the surface of the chuck but are extended above the surface when it is desired to push up the wafer. The pushing pins can be driven electrically, pneumatically, magnetically or electro-magnetically. Vacuuming grooves 1401 cover most of the wafer area surrounding the pushing pins. The chuck surface can also include small location pins 1405 to locate and constrain the position of the wafer on the chuck.

FIG. 15 schematically illustrates an exemplary imprint subsystem 1003. The imprint subsystem comprises a top pressure chamber 1501, a bottom pressure chamber 1507, and a sliding chuck 1505 in the middle. To imprint, a mask/wafer set is transferred to the sliding chuck 1505. The bottom pressure chamber is raised up: first, to lift the sliding chuck and second, to closely contact the top pressure chamber. There are sealing O-rings on all contact surfaces. Thus, a sealed chamber space surrounding the mask/wafer set is formed by the top pressure chamber in contact with the bottom pressure chamber. After sealing, the chamber is filled with pressurized fluid to press the mask against the wafer. Either thermal imprint or UV imprint may be performed. For thermal imprint, heaters inside the chamber can heat the wafer and the mask. For UV imprint, UV radiation can be introduced through a UV-transparent window in the chamber (e.g. on top of the chamber). The UV light can be generated by a UV light source 1503 disposed outside the window. After the pressing, the pressure inside the chamber is released. The bottom chamber is lowered to lower the sliding chuck and continues to lower to its starting position. An air cylinder 1513 underneath the bottom pressure chamber 1507 drives the chamber up or down and holds the chamber sealed while pressurized. The whole press unit is supported by a frame 1509. Pneumatic control panel 1511 and control computer 1515 can be installed in other space inside the frame to automate the process. A monitor 1517 can sit on a stand connected to the frame to display an operator interface and process parameters.

Operation of the system starts with loading the mask and the wafer onto the alignment subsystem. The wafer is aligned to the mask. Then, the wafer contacts with the mask. After that, the pushing pins on the chuck are charged to press wafer against mask at predetermined locations. One or more pins may be used to generate one or more contacting areas between the mask and wafer. The press enhances adhesion at the contacting areas which holds the mask and the wafer in alignment for following steps. Then, the pushing pins are released, and the aligned mask/wafer set is transferred to the imprint subsystem for imprinting.

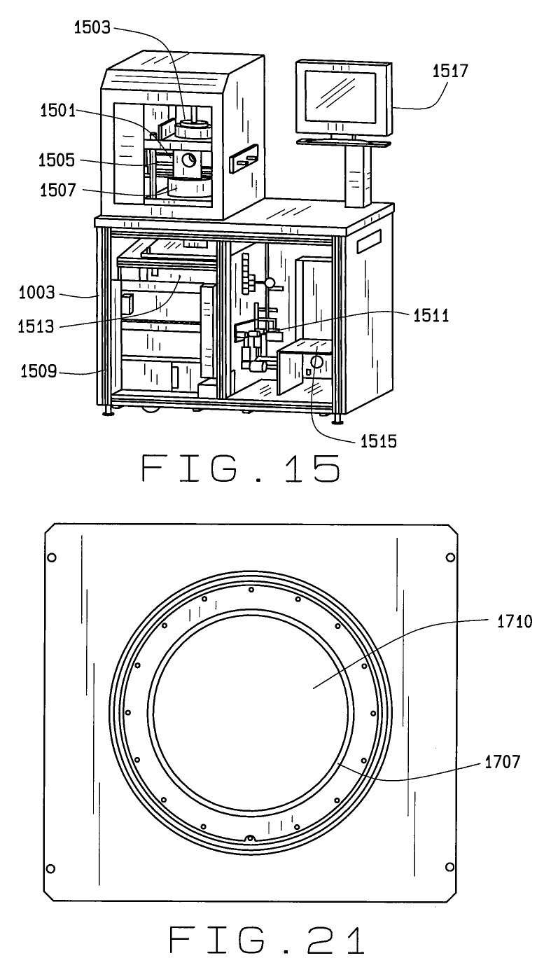

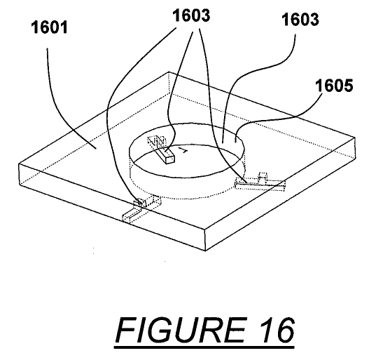

Referring to FIG. 16, a transfer clamp fixture 1601 may be used to transfer the aligned mask/wafer set from the alignment subsystem to the imprint subsystem. Three clamps 1603 can be applied. The fixture functions as a mask chuck to hold the mask for aligning wafer. Center area 1603 can be open or can be a transparent window so that a microscope may view alignment marks. After the wafer and mask are aligned, the three clamps are applied to hold the wafer against the mask. The three-point holding maintains the alignment for the remaining process. The fixture is then transferred and loaded onto the imprint subsystem. The clamps are retracted before imprint. Thus, imprint with alignment is achieved.

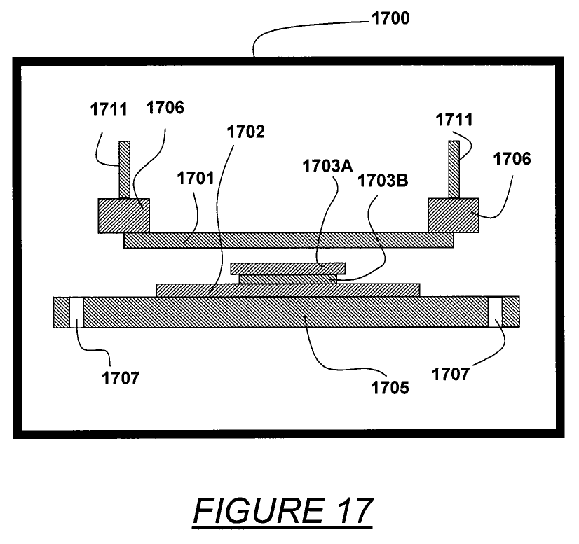

Further in details of the imprint subsystem are illustrated in FIGS. 17 to 27.

FIG. 17 illustrates a sealing arrangement for the imprint subsystem. The mask 1703A and wafer 1703B form a mask/wafer set 1703. The set 1703 is supported within chamber 1700 by a wafer chuck 1705 and a flexible membrane 1702. A second membrane 1701 is located above the mask/wafer set. The second membrane 1701 is held around the edge by a ring 1706. The ring can be driven down by actuator assembly 1711 to contact membrane 1702 around the mask/wafer set. The contact forms a seal to prevent gas from leaking into the sealed area. Through-holes 1707 adjacent the edge of the wafer chuck provide gas exchange channels between the upper space and the lower space to maintain gas pressure equilibrium.

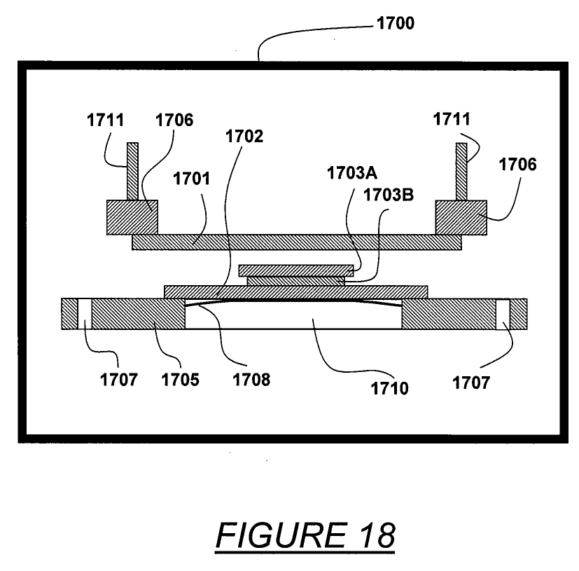

FIG. 18 illustrates an alternative sealing arrangement. The central area of wafer chuck 1705 has a hole 1710. The lateral area of the hole is smaller than that of membrane 1702 and larger than that of mask/wafer set 1703. A mechanical support 1708 can be used support the weight of the membrane and the mask/wafer set.

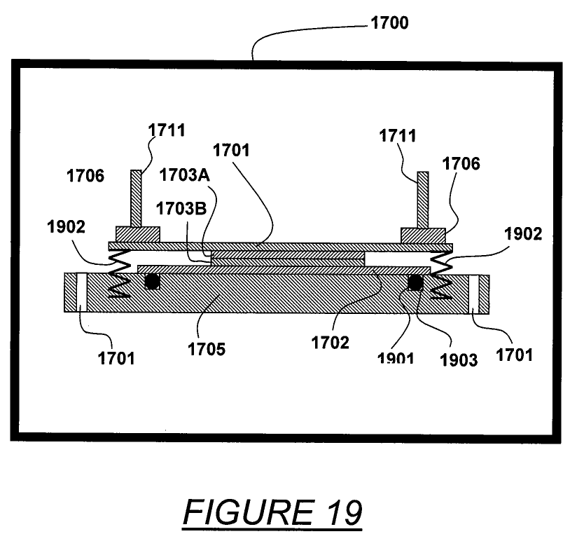

FIG. 19 illustrates the operation of the sealing structures of FIGS. 17 and 18. In operation, mask/wafer set 1703A, 1703B is supported by flexible membrane 1702 and a substrate holder 1705. A rigid ring 1706 with a flexible sealing membrane 1701 is placed on the springs 1902, which can be installed on the substrate holder. Initially there are openings between 1701 and 1702 for air flow. Upon evacuation of chamber 1700, the air trapped between the molding surface and moldable surface is evacuated through those gaps. Then, rigid ring 1706 is pressed down by actuators 1711, closing the gaps between membrane 1701 and membrane 1702 on the edge and sealing the interface of the molding surface and moldable surface. High-pressure fluid, preferably gas, is then pumped into chamber 1700, to uniformly press the mold against the moldable layer for imprinting. Holes 1701 on substrate holder 1705 balance the pressure inside the chamber. The sealing force can be controlled by adjusting the pushing force of actuator assembly 1711. The actuator assembly can be driven by solenoids, bellow pistons, electrical motors, or pneumatic cylinders. Membrane 1701 may be clamped onto rigid ring 1706, and membrane 1702 may be clamped onto substrate holder 1705 for easy separation of the membranes after imprinting. The sizes of mask and wafer are not necessarily the same. A mask and wafer of different form factors can be handled by the apparatus described above. Furthermore, an O-ring groove 1903 can be machined on the surface of substrate holder 1705 underneath the edge of membrane 1702. An O-ring 1901 on the substrate holder installed inside the vacuum groove improves the sealing. Alternatively, the groove and O-rings can be placed on both the holder and the rigid ring.

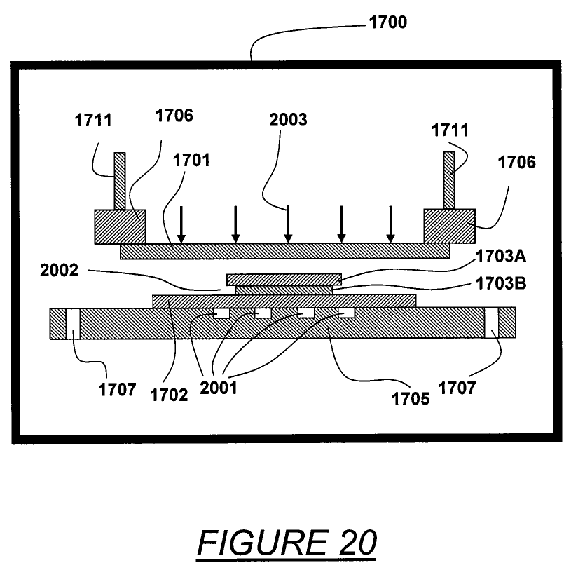

FIG. 20 illustrates an alternative arrangement wherein a plurality of grooves 2001 on substrate chuck 1705 can apply vacuum to hold flexible membrane 1702 against the chuck surface. The flexible membrane 1702 has through-holes (not shown) at predetermined locations, so that vacuum can be applied through the membrane to hold the mask or wafer against the membrane surface. During imprinting, fluid pressure can be applied to membrane 1702 through grooves 2001 and to membrane 1701 from upper space 2003. After imprint, vacuum can be applied to grooves 2001 and upper space 2003. Pressurized fluid can then be applied to interim space 2002 for easy separation of the mask/wafer set 1703.

FIG. 21 is a top view of an advantageous substrate holder 1705. Opening 1710 allows the passage of imprint fluid as well as thermal heating or UV light. Holes 1707 allow the fluid to flow between the top space and the bottom space to balance pressure.

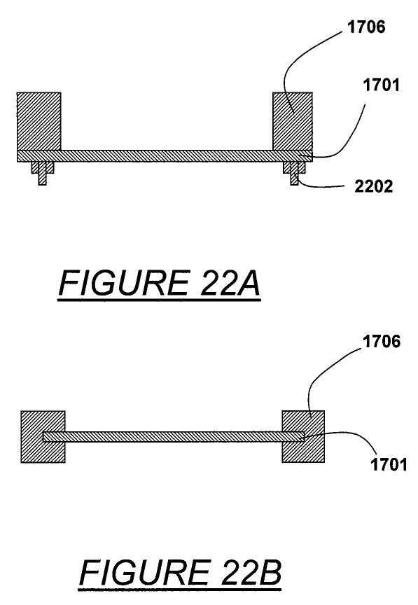

FIGS. 22A and 22B illustrate mechanisms to hold the flexible sealing membranes onto their support structures. FIG. 22A shows magnets 2202 placed on metal ring 1706 to hold the flexible sealing membrane 1701 to the rigid ring 1706. FIG. 22B shows the flexible membrane 1701 mechanically clamped to the rigid ring 1706. Similar clamping mechanisms may also be used to clamp flexible sealing membrane 1702 onto substrate holder 1705.

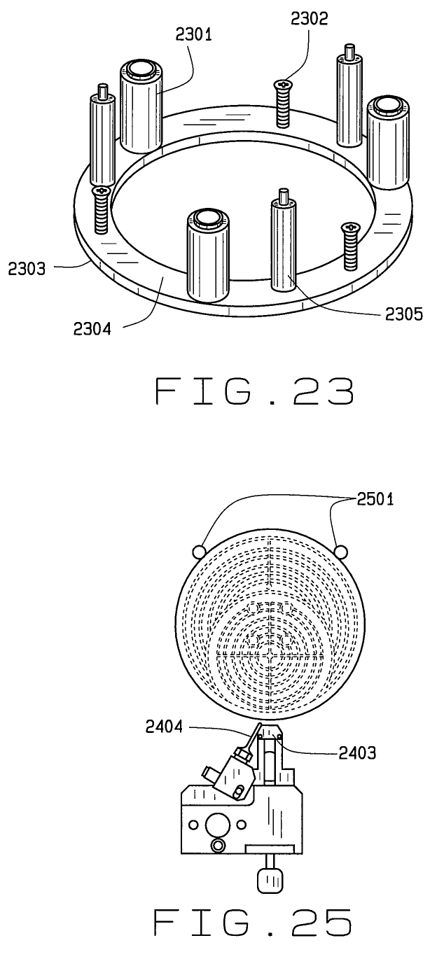

FIG. 23 illustrates an advantageous actuator assembly 1711 comprising a first rigid ring 2303 adjacent a second rigid ring 2304. The two rings can be held together by a plurality (here 3) of return springs 2302. Ring 2303 is connected to the chamber through a plurality (e.g. 3) of supports 2305. A plurality of solenoids 2301 are mounted evenly spaced along the perimeter of ring 2303. The moving rods of the solenoids can be extended to push ring 2304 when the solenoids are electrically charged. The pushing forces overcome the holding forces of the return springs and push ring 2304 down. When the solenoids are discharged, the return springs pull ring 2304 back to its original position. The ring shape of the actuator assembly facilitates a uniform pressing along a circular perimeter that fits with the shape of circular sealing membranes. Alternatively, pneumatic cylinders, inflatable bellows, or piezo actuators may be used in place of the solenoids.

For UV imprinting, one of the flexible membranes 1701 or 1702 is preferably transparent to UV radiation, which allows the UV curing of the moldable layer. Chemical treatment, physical treatment or a combination of both may be applied to the surfaces of the membranes to change their surface adhesion property, in order to facilitate release of mask and wafer from the membrane surfaces.

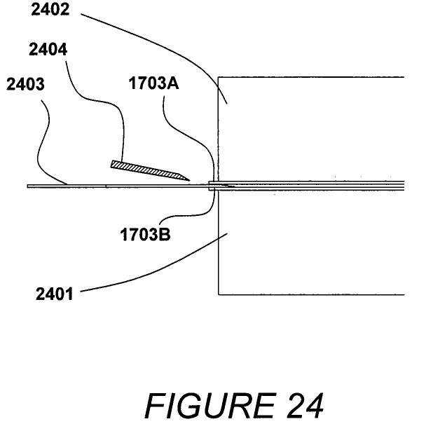

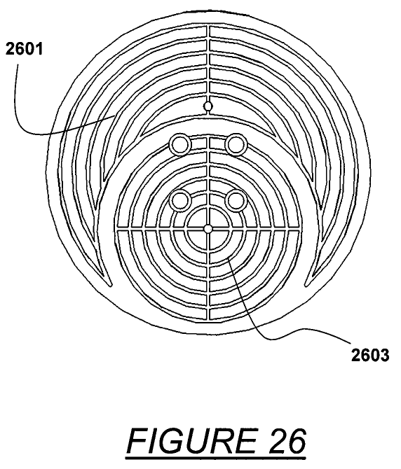

FIGS. 24 to 26 illustrate a mask/wafer separator. FIG. 24 is a side view and FIG. 25 is a top view. The separator has two vacuum chucks 2401 and 2402 to hold by vacuum the non-imprinted surfaces of the mask/wafer set 1703. A thin blade 2403 can be inserted between the mask and the wafer from the edge to separate the mask and the wafer at the insertion location. A nozzle 2404 can be directed at the location of the insertion blade. A high pressure gas jet from the nozzle is directed coplanar to the surface of the inserted blade. The gas jet is thus directly blown into the intermediate space between the separated mask/wafer surfaces, and the jet further expands the separated area. When the chucks are moved away from each other, the combined effects of the gas jet from edge and the vacuum holding on the non-imprinted surfaces completely separate the whole imprinted area.

An alternative separation process is to use one chuck to hold a non-imprinted surface of either mask or wafer and position the other chuck away from the non-imprinted surface by a predetermined gap. When the gas jet is blown to separate, the non-holding chuck is bending up and the separated area can be further expanded. Vacuum on the non-holding chuck is turned on with the air jet. The vacuum facilitates the expansion of the separated area. After the whole imprinted area is separated, the vacuum from the non-holding chuck will prevent flying-away. Stopping rods 2501 can be installed at edges of the chucks to provide additional safety in case the vacuum fails to pick up. The predetermined gap helps to prevent the mask or wafer from over-bending during the separation. The blade may be driven in/out manually by operator or automatically by pneumatic, electric or electro-magnetic actuators.

FIG. 26 illustrates advantageous chucks for the separator. This embodiment has two sets of vacuum grooves 2601 and 2602 to fit two different mask/wafer sizes. Vacuum on both groove set 2601 and groove set 2603 works for a larger size. Vacuum on groove set 2603 works for a smaller size.

It can now be seen that in one aspect the invention is an apparatus for performing imprint lithography on a substrate having a moldable surface. The apparatus comprises a mold having a molding surface for imprinting the moldable surface, a common frame or body, an alignment module secured to the common frame or body and at a nearby location, a pressing module secured to the common frame or body. The alignment module comprises an aligner for aligning the molding surface and the moldable surface into a precise lateral position. The pressing module comprises a source of pressure to press the molding surface and the moldable surface together to imprint the molding surface into the moldable surface. Advantageously, the alignment module includes a retention mechanism to retain the molding surface and the moldable surface in the precise lateral position during transport from the alignment module to the pressing module. The pressing module may advantageously include a separation mechanism to separate the mold and the substrate after imprinting.

In advantageous embodiments, the substrate comprises a solid material, such as silicon, with a moldable polymer coating. The alignment module comprises optical aligners for aligning optical marks on the mold and the substrate, and the retention mechanism can be clamping, sub-imprint pressing, or heating to promote surface adhesion between the mold and the substrate.

An advantageous pressing module can be a high precision mechanical press but preferably comprises apparatus for direct fluid pressure imprinting including a seal around the mold/substrate interface, a pressure chamber and a source of pressurized fluid. In a preferred arrangement, the mold/substrate assembly is disposed within a pressure chamber, sealed between a pair of flexible membranes, and subjected to pressurized fluid introduced into the chamber.

An advantageous separation mechanism comprises a knife-edge blade for insertion at the mold/substrate edge, a gas jet for enhancing the separation begun by the blade insertion and vacuum chucks to pull apart the separated mold and substrate.

It is to be understood that the above described embodiments are illustrative of only a few of the many embodiments that can represent applications of the invention. Numerous and varied other arrangements can be made by those skilled in the art without departing from the spirit and scope of the invention.

1. An apparatus to perform imprint lithography on a substrate having a moldable surface comprising:
a mold having a molding surface for imprinting the moldable surface;
a common frame or body;
am alignment module secured to the common frame or body at a first location, the alignment module comprising an aligner for aligning the molding surface and the moldable surface in a precise lateral position;
a pressing module secured to the common frame or body at a second location spaced apart from the first location, the pressing module comprising a source of pressure to press the molding surface and the moldable surface together to imprint the moldable surface;
wherein the alignment module further comprises a retention mechanism to form a mold/substrate assembly with the aligned molding surface and the moldable surface in said precise lateral position for transport from the alignment module to the pressing module.

2. The apparatus of claim 1 wherein the mold has a molding surface for imprinting a pattern of recessed and projecting features having at least one such feature with a minimum dimension of less than 200 nanometers.

3. The apparatus of claim 1 wherein the alignment module comprises an optical aligner.

4. The apparatus of claim 1 wherein the retention mechanism comprises a clamping mechanism for clamping together the aligned mold and substrate or a pressing mechanism to press together the aligned mold and substrate or a heating mechanism to heat the aligned mold or substrate.

5. The apparatus of claim 1 wherein the pressing module further comprises a separation mechanism to separate the mold and the substrate after imprinting.

6. The apparatus of claim 5 wherein the separation mechanism comprises a knife-edge blade to begin separation and a gas jet to enhance the separation begun by the blade.

7. The apparatus of claim 6 further comprising at least one chuck attached to the mold or the substrate to pull apart the apart the mold and substrate upon separation.

8. The apparatus of claim 1 wherein the pressing module comprises a pressure chamber for receiving the aligned mold/substrate assembly, a sealing mechanism to seal the mold/substrate assembly and a source of pressurized fluid to press together the sealed assembly.

9. The apparatus of claim 8 wherein the sealing mechanism comprises a pair a flexible membranes that can be clamped together around the mold/substrate assembly.

10. The apparatus of claim 1 wherein said retention mechanism comprises at least one pushing pin for pressing together the mold and the substrate at a pressure less than required for the desired imprinting.

11. The apparatus of claim 1 wherein the alignment module comprises an alignment stage to move the substrate relative to the mold, a substrate chuck connected to the alignment stage, a mold holder connected to the frame to hold the mold above the alignment stage, and an alignment microscope connected to the frame above the mold holder to image features on the mold and on the substrate.

12. The apparatus of claim 11 wherein, said alignment stage comprises:
a first single axis stage with a first hollow moving block;
a second single axis stage with a second hollow moving block mounted on top of the first moving block of said first single axis stage in such way that the moving axis of the second stage is perpendicular to moving axis of the first stage, and the hollow area of the second moving block overlaps the hollow area of the first moving block;
a Z-movement stage with a moving rod mounted on the second moving block in such way that said Z-movement stage overlaps the hollow areas of the two single-axis stages and extends downward, the moving axis of the Z-movement stage oriented perpendicular to plane of movements of the first and second stage;
a leveling part mounted on top of said moving rod that can provide and lock angular movements.

13. The apparatus of claim 11 wherein, said pushing pin is driven by hydraulic force.

14. The apparatus of claim 11 wherein the top end of said pushing pin contacts the substrate when the pin is retracted.

15. The apparatus of claim 11 wherein the top end of said pushing pin contact the substrate when the pin is extended.

16. The apparatus of claim 11 wherein said pushing pin comprises an enlarged end.

17. The apparatus of claim 11 wherein, the holder comprises one or more moveable arms flats, each said movable arm flat comprising a ball on its end extending into the intermediate space of loaded mold and substrate.

18. The apparatus of claim 17 wherein each said ball has precise predetermined diameter to perform as a precise spacer to separate loaded mold and substrate.

19. The apparatus of claim 11 wherein each said movable arm flat can extend into said intermediate space by rotating or sliding.

20. The apparatus of claim 11 wherein, said movable arm flat is driven by hydraulic piston actuator.

21. The apparatus of claim 11 further comprising an operator interface panel with electronic or pneumatic switches.

22. The apparatus of claim 11 comprising an alignment microscope that is moveable to search for features on the mold and the substrate.

23. The apparatus of claim 11 wherein said frame includes a lock to secure positioning of said mold chuck.

24. The apparatus of claim 10 wherein, said imprint module comprises:
a frame; and mounted on the frame:
a chamber to perform direct-fluid-press imprinting;
a pneumatic line and valve panel connected to the chamber to supply vacuum, pressurized gas and venting;
an electronic system to control operation of said panel; and
a computer with software to control said electronic system.

25. The apparatus of claim 24 wherein, said pressing module comprises two bodies that fit together to form a seal chamber for vacuum ad pressure when they are pressed against each other;
a slide chuck to load and unload a mold and a wafer disposed between the two bodies;
a heating element inside the chamber to raise temperatures of the mold and the substrate;
a radiation source located outside the chamber to direct ultraviolet light onto the mold and the substrate through a window on at least one of said bodies;
a means for sealing edges of the mask and substrate assembly when direct-fluid-pressure is applied.
